(19) United States
(12) Patent Application Publication
(10) Pub. No.: US 2009/0047528 A1
(43) Pub. Date: Feb. 19, 2009

(54) SURFACE TREATMENT METHOD OF ALUMINUM EXTRUDING DIE, AND ALUMINUM EXTRUDING DIE

(75) Inventors: Teruo Tachi, Tochigi (JP); Koichi Tanaka, Tochigi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: SHOWA DENKO K.K, Minato-ku ,Tokyo (JP)

(21) Appl. No.: 11/997,213

(22) PCT Filed: Jul. 28, 2006
(86) PCT No.: PCT/JP2006/315433

§ 371 Date: Jan. 29, 2008

Related U.S. Application Data
(60) Provisional application No. 60/704,875, filed on Aug. 3, 2005.

(30) Foreign Application Priority Data
Jul. 29, 2005 (JP) 2005-221266

(51) Int. Cl. B32B 15/04; C23C 16/22

(52) U.S. Cl. 428/457; 427/249.1

(57) ABSTRACT

A surface treatment method of an aluminum extruding die having wear resistance and separation resistance is provided. The surface treatment method of an aluminum extruding die includes a first nitriding treatment step for forming a diffusion hardened layer 6 containing carbon and nitrogen at a surface layer portion of a die main body 5 by heating and retaining the die main body 5 made of tool steel in a nitriding gas atmosphere containing carburizing gas, and a second nitriding treatment step for forming a compound layer 7 substantially not containing carbon on a surface of the diffusion hardened layer 6 by heating and retaining the die main body 5 to which the first nitriding treatment was executed in a nitriding gas atmosphere not containing carburizing gas.

This application claims priority to Japanese Patent Application No. 2005-221266 filed on Jul. 29, 2005 and U.S. Provisional Application Ser. No. 60/704,875 filed on Aug. 3, 2005, the entire disclosures of which are incorporated herein by reference in their entireties.

### CROSS REFERENCE TO RELATED APPLICATIONS

This application is an application filed under 35 U.S.C. 111(a) claiming the benefit pursuant to 35 U.S.C. §119(e)(1) of the filing date of U.S. Provisional Application Ser. No. 60/704,875 filed on Aug. 3, 2005, pursuant to 35 U.S.C. 111(b).

### TECHNICAL FIELD

The present invention relates to a surface treatment method of an aluminum (including its alloy) extruding die having wear resistance and separation resistance, and also relates to an aluminum extruding die obtained by the method.

### BACKGROUND ART

The following description sets forth the inventor's knowledge of related art and problems therein and should not be construed as an admission of knowledge in the prior art.

Aluminum materials have been widely used for construction materials, etc., because of the lightweight and the excellent corrosion resistance. Among these aluminum materials, in order to obtain components required in brightness, extrusion molding forming has been widely adopted. In such extruding die, JIS (Japanese Industrial Standards) SKD61-based or SKD62-based tool steel is used as the die base metal.

Furthermore, wear progression of a bearing surface, etc., of a die due to extrusion of an aluminum alloy has a great influence on the dimension and/or the surface quality of the obtained extruded material. Especially in the case of an aluminum alloy of 3xxx series, the bearing surface, etc., of the die readily wears. Under the circumstances, for the purpose of controlling such wear, it is known that the aforementioned tool steel is subjected to various kinds of nitriding treatments (see, e.g., Japanese Unexamined Laid-open Patent Publication No. H10-30164, hereinafter referred to as “Patent Document 1”).

The aforementioned nitriding treatment of an extruding die causes a nitride compound layer mainly made of Fe₂N and Fe₃N generally called a compound layer at the outermost surface and a diffusion hardened layer in which nitrogen is diffused at the base metal side.

In this case, the compound layer of the outermost surface is high in hardness such as 1,000 MHv or more, and low in affinity with the contacting aluminum alloy as compared with the base metal, which is effective to control the wear of the die and the adhesion of an aluminum alloy at the time of the extrusion. Moreover, the diffusion hardened layer at the base metal side functions as an intermediate layer for preventing the separation due to the large hardness difference between the compound layer and the base metal.

At an aluminum extruding step, since a final configuration is obtained only by extruding an aluminum alloy billet, the stress applied to the die surface becomes quite large. On the other hand, a diffusion hardened layer increased in hardness by nitrogen diffusion tends to become brittle. For this reason, the diffusion hardened layer may cause cracks by, for example, the stress of the extruding, causing a separation of the diffusion hardened layer. Such separation of the diffusion hardened layer causes defective configuration and/or deteriorated surface quality of the extruded material, and also may sometimes cause such a trouble that separated pieces mix into an extruded material. Therefore, a nitrided extruding die is required to have separation resistance.

That is, in gas nitriding processing in which no carbon source is added to nitriding gas (gas for nitriding treatment), solid solution carbon C in the material will be moved into the base metal side by diffusing nitrogen N from the base metal surface. Consequently, the C concentration in the diffusion hardened layer decreases while the N concentration in the diffusion hardened layer increases, which results in a brittle nitrided layer. Such embrittlement of a diffusion hardened layer tends to cause generation and progress of cracks when large stress is applied at the time of extruding. As a result, large surface defects, such as, e.g., a separation of the most part of the diffusion hardened layer, may readily occur.

In order to control the brittleness of the nitrided layer, it is effective to employ a method in which not only nitrogen but also carbon are simultaneously diffused to thereby form not only nitride but also carbonitride or carbide which is a compound slightly low in hardness and high in toughness as compared with nitride. As such method, there exist gas soft nitriding treatment in which nitriding treatment is performed in an atmosphere containing carbon source and salt bath nitriding treatment. Thus, as disclosed in the aforementioned Patent Document 1, there is proposed technique to improve the separation characteristic from the base metal by executing carbonitriding in a nitriding gas atmosphere to which gas having carbon source is added.

However, an extruding temperature of an aluminum alloy is usually 450° C. or above. Among other things, the temperature of the bearing portion of the die by which the extruding aluminum alloy is worked with strong force to thereby become higher temperature often hits 500° C. or above. On the other hand, a compound layer mainly formed by Fe₂N and Fe₃N has a characteristic capable of containing a large amount of solid solution carbon. In the case of executing the aforementioned carbonitriding treatment, however, it is known from research results that the compound layer becomes readily decomposable at high temperatures (about 500° C. or above) as the amount of solid solution carbon in the compound layer increases.

FIG. 1A shows a result of an EPMA analysis of a sample subjected to gas soft nitriding treatment under the conditions of heating temperature of 570° C.×retention time of 3 hours in the mixed gas atmosphere of 50% NH₃+50% carburizing gas (RX gas). On the other hand, FIG. 1B shows a result of an EPMA analysis of a sample subjected to salt bath nitriding treatment under the condition of heating temperature of 580° C.×retention time of 2 hours. In these figures, the “white layer” denotes a compound layer. With these methods, a compound layer formed at the outermost surface also becomes nitride including a large amount of carbon. Here, it is considered that the reasons that a compound layer containing a large amount of carbon readily decomposes at high temperatures are because the bonding strength of C with respect to Fe is weaker than that of N with respect to Fe.

Thus, a compound layer including solid solution carbon has a defect of readily decomposing than a compound layer including only nitride when exposed to a high temperature during extruding processing. Consequently, the compound layer remarkably decreases in thickness during the extruding processing not only by simple wear but also by decomposition.

As discussed above, since a compound layer containing carbon readily disappears by decomposition, a die disclosed in Patent Document 1 has a problem that the compound layer readily decomposes and disappears to thereby cause an exposure of the diffusion hardened layer during the extruding processing though the diffusion hardened layer can be improved in toughness. Once the compound layer disappeared and therefore the diffusion hardened layer is exposed, although the diffusion hardened layer is high in hardness, such as 900 to 1,100 MHv, the diffusion hardened layer will rapidly wear since the affinity with the aluminum alloy becomes large in the same manner as with the base metal. This in turn causes a trouble that an obtained extruded material greatly deteriorates in surface quality.

The description herein of advantages and disadvantages of various features, embodiments, methods, and apparatus disclosed in other publications is in no way intended to limit the present invention. Indeed, certain features of the invention may be capable of overcoming certain disadvantages, while still retaining some or all of the features, embodiments, methods, and apparatus disclosed therein.

Other objects and advantages of the present invention will be apparent from the following preferred embodiments.

### DISCLOSURE OF INVENTION

The preferred embodiments of the present invention have been developed in view of the above-mentioned and/or other problems in the related art. The preferred embodiments of the present invention can significantly improve upon existing methods and/or apparatuses.

The present invention was made to solve the aforementioned problems of conventional technique, and aims to provide a surface treatment method of an aluminum extruding die having wear resistance and separation resistance, an aluminum extruding die obtained by the method, and a production method of an aluminum extruding die.

The present invention provides the following means.

[1] A surface treatment method of an aluminum extruding die, comprising:

a first nitriding treatment step for forming a diffusion hardened layer containing carbon and nitrogen at a surface layer portion of a die main body by heating and retaining the die main body made of tool steel in a nitriding gas atmosphere containing carburizing gas; and

a second nitriding treatment step for forming a compound layer substantially not containing carbon on a surface of the diffusion hardened layer by heating and retaining the die main body to which the first nitriding treatment was executed in a nitriding gas atmosphere not containing carburizing gas.

[2] The surface treatment method of an aluminum extruding die as recited in the aforementioned Item 1, wherein, at the first nitriding treatment step, heating temperature is 500 to 580° C.

[3] The surface treatment method of an aluminum extruding die as recited in the aforementioned Item 1 or 2, wherein, at the first nitriding treatment step, retaining time is 1 to 5 hours.

[4] The surface treatment method of an aluminum extruding die as recited in any one of the aforementioned Items 1 to 3, wherein, at the first nitriding treatment step, the carburizing gas is converted gas of butane or propane, and the nitriding gas is NH₃ gas, or mixed gas containing NH₃ gas and non-nitriding gas.

[5] The surface treatment method of an aluminum extruding die as recited in the aforementioned Item 4, wherein the carburizing gas is RX gas.

[6] The surface treatment method of an aluminum extruding die as recited in any one of the aforementioned Items 1 to 5, wherein, at the first nitriding treatment step, the diffusion hardened layer is formed to have a thickness of 50 μm or more.

[7] The surface treatment method of an aluminum extruding die as recited in any one of the aforementioned Items 1 to 6, wherein, at the second nitriding treatment step, heating temperature is 500 to 580° C.

[8] The surface treatment method of an aluminum extruding die as recited in any one of the aforementioned Items 1 to 7, wherein, at the second nitriding treatment step, retaining time is 1 to 5 hours.

[9] The surface treatment method of an aluminum extruding die as recited in any one of the aforementioned Items 1 to 8, wherein, at the second nitriding treatment step, the nitriding gas is NH₃ gas, or a mixed gas containing NH₃ gas and non-nitriding gas.

[10] The surface treatment method of an aluminum extruding die as recited in any one of the aforementioned Items 1 to 9, wherein, at the second nitriding treatment step, the diffusion hardened layer is formed to have a thickness of 2 to 10 μm.

[11] The surface treatment method of an aluminum extruding die as recited in any one of the aforementioned Items 1 to 10, wherein re-nitriding treatment including the second nitriding treatment step is executed to the die when a thickness of the compound layer formed at the second nitriding treatment step is decreased or disappeared by extrusion.

[12] The surface treatment method of an aluminum extruding die as recited in any one of the aforementioned Items 1 to 11, wherein the die is for extruding 3xxx series aluminum alloy.

[13] The surface treatment method of an aluminum extruding die as recited in any one of the aforementioned Items 1 to 12, wherein the die is made of hot work tool steel to which hardening treatment and tempering treatment were executed.

[14] An aluminum extruding die processed by the surface treatment method of an aluminum extruding die as recited in any one of the aforementioned Items 1 to 13.

[15] An aluminum extruding die in which a diffusion hardened layer containing carbon and nitrogen is formed at a surface layer portion of a die main body made of tool steel and a compound layer not substantially containing carbon is formed at a surface of the diffusion hardened layer.

[16] A production method of an aluminum extruding die including the surface treatment method of an aluminum extruding die as recited in any one of the aforementioned Items 1 to 13.

The present invention demonstrates the following effects.

According to the invention as recited in the aforementioned Item [1], in order to attain the structure in which the compound layer of the surface of the die is relatively hard to decompose and hard to cause a separation of the diffusion hardened layer, at the first nitriding treatment step, after executing nitriding treatment (first nitriding treatment) in a nitriding gas atmosphere containing carburizing gas having carbon source, a nitriding treatment (second nitriding treatment) is subsequently executed in a nitriding gas atmosphere not including carburizing gas at a second nitriding treatment step. This prevents embrittlement of the diffusion hardened layer by diffusing both nitrogen and carbon in the diffusion hardened layer to thereby prevent the separation of the diffusion hardened layer. In addition, by reducing the carbon concentration in the compound layer formed at the outermost surface as much as possible, formation of carbide or carbonitride which is a compound with bonding strength to Fe weaker than iron nitride simple substance is controlled, thereby forming a compound layer hard to decompose especially at high temperature regions. Thus, an aluminum extruding die of nitrided layer structure having wear resistance and separation resistance can be obtained. As mentioned above, the aluminum extruding die to which the surface treatment was executed by the method of the present invention has nitrided layer structure having wear resistance and separation resistance, and therefore an effect of reducing the amount of wear can be demonstrated in the case of a die for extruding an aluminum extruded pipe at a relatively high extruding temperature. Furthermore, since the die hardly causes troubles due to the occurrence of separation, further improvement in quality of an extruded article and productivity can be expected.

According to the invention as recited in the aforementioned Item [2], softening of a die can be prevented, and a required thickness of a diffusion hardened layer and high productivity can be secured assuredly.

According to the invention as recited in the aforementioned Item [3], a diffusion hardened layer with a sufficient thickness can be formed assuredly, and high productivity can be secured assuredly.

According to the invention as recited in the aforementioned Item [4], a diffusion hardened layer can be formed assuredly.

According to the invention as recited in the aforementioned Item [5], a diffusion hardened layer can be formed more assuredly.

According to the invention as recited in the aforementioned Item [6], a die excellent in separation resistance and wear resistance can be provided.

According to the invention as recited in the aforementioned Item [7], softening of a die can be prevented, and a required thickness of a diffusion hardened layer and high productivity can be secured assuredly.

According to the invention as recited in the aforementioned Item [8], the C concentration in the compound layer can be reduced assuredly, and the diffusion of C in the diffusion hardened layer toward the base metal can be prevented assuredly.

According to the invention as recited in the aforementioned Item [9], a compound layer can be formed assuredly.

According to the invention as recited in the aforementioned Item [10], high productivity can be secured.

According to the invention as recited in the aforementioned Item [11], when the compound layer decreased or disappeared due to extrusion and the diffusion hardened layer is exposed so that the sudden wear can be advanced, a compound layer low in carbon concentration and hard in decomposition is freshly formed, thereby enabling the re-use of the die. In this case, when treatment including the aforementioned first nitriding treatment step and the second nitriding treatment step is executed as the aforementioned re-nitriding treatment, the re-nitriding treatment causes a further increased thickness of the diffusion hardened layer, which in turn improves the function of the diffusion hardened layer as an inclined layer which supports the compound layer and gradually reduces the hardness to the base metal. This results in the structure which hardly causes separation of the diffusion hardened layer.

According to the invention as recited in the aforementioned Item [12], it is possible to provide a die excellent in wear resistance for extruding an aluminum alloy of 3xxx series which readily causes wear of the die among various aluminum alloys.

According to the invention as recited in the aforementioned Item [13], a die in which the base metal is high in intensity can be provided.

According to the invention as recited in the aforementioned Item [14] and [15], both nitrogen and carbon are diffused in the diffusion hardened layer, which prevents the separation of the diffused hardened layer by controlling the embrittlement of the diffusion hardened layer. In addition, the carbon concentration in the compound layer formed at the outermost surface is reduced as much as possible to prevent the formation of carbide and carbonitride which is a compound with bonding strength to Fe weaker than an iron nitride simple substance, which controls the decomposition of the compound layer especially at high temperature regions. Thus, the aluminum extruding die to which the surface treatment was executed by the method of the present invention has the nitrided layer structure having wear resistance and separation resistance. The die can demonstrate an effect of reducing the amount of wear of the die in the case of an aluminum pipe extruding die at a relatively high extruding temperature, and hardly causes troubles due to the separation of the hardened layer. Thus, the quality of an extruded material can be improved and the improvement in productivity can also be expected.

According to the invention as recited in the aforementioned Item [16], the same effects as those of the invention as recited in any one of the aforementioned Items [1] to [13] can be attained.

The above and/or other aspects, features and/or advantages of various embodiments will be further appreciated in view of the following description in conjunction with the accompanying figures. Various embodiments can include and/or exclude different aspects, features and/or advantages where applicable. In addition, various embodiments can combine one or more aspect or feature of other embodiments where applicable. The descriptions of aspects, features and/or advantages of particular embodiments should not be construed as limiting other embodiments or the claims.

### BRIEF DESCRIPTION OF DRAWINGS

The preferred embodiments of the present invention are shown by way of example, and not limitation, in the accompanying figures, in which:

FIG. 1A is a figure (graph) showing a result of an EPMA analysis of a cross-section of a sample to which gas soft nitriding treatment was executed;

FIG. 1B is a figure (graph) showing a result of an EPMA analysis of a cross-section of a sample to which salt bath nitriding treatment was executed;

FIG. 2 is a figure (graph) showing a result of an EPMA analysis of a cross-section of a sample of Example 1;

FIG. 3 is a figure (graph) showing measured results of the surface roughness of dies of Example 2 and Comparative Examples 1 and 2 in a state before and after the extrusion;

FIG. 4 is figures (photographs) showing brittle evaluation results by Micro-Vickers indentation tests of samples of Example 3 and Comparative Example 3;

FIG. 5 is a schematic cross-sectional view showing an aluminum extruding die according to an embodiment of the present invention; and

FIG. 6 is an enlarged schematic cross-sectional view showing a bearing portion of the die.

### BEST MODE FOR CARRYING OUT THE INVENTION

In the following paragraphs, some preferred embodiments of the invention will be described by way of example and not limitation. It should be understood based on this disclosure that various other modifications can be made by those in the art based on these illustrated embodiments.

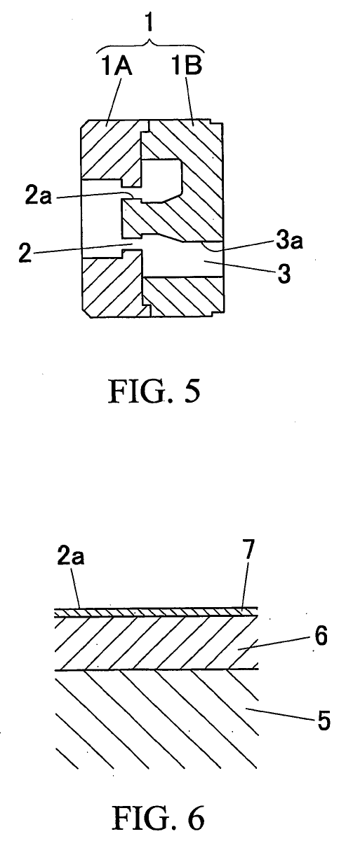

FIG. 5 is a schematic cross-sectional view showing a die for aluminum (including its alloy) extrusion according to an embodiment of the present invention. This die is specifically a porthole die 1. This porthole die 1 is used for extruding a pipe member (not shown) circular in cross-section as an extruded member, and comprised of a female die 1A and a male die 1B combined at the time of extrusion.

This porthole die 1 has a bearing hole 2 of a cross-sectional configuration corresponding to the cross-sectional configuration of a member to be extruded (i.e., circular cross-sectional configuration) and a plurality of portholes 3. In this die 1, after a billet flows into from the porthole 3, an extruded material is extruded through the bearing hole 2.

At least the bearing surface 2a of this die 1 is treated by the surface treatment method according to the present invention. Furthermore, the port surface 3a of this die 1 is also treated by the surface treatment method according to the present invention. More specifically, in this embodiment, the entire surface of this die 1 is surface-treated.

In the present invention, however, the die for aluminum extrusion is not limited to a porthole die, and can also be, for example, a bridge die, a solid die, a hollow die, a semi hollow die, or a flat die.

FIG. 6 is an enlarged schematic cross-sectional view showing the bearing portion of this die 1. The die main body 5 of this die 1 is made of tool steel. More specifically, it is made of hot work tool steel to which hardening treatment and tempering treatment were executed. At the surface layer portion of this die main body 5, a diffusion hardened layer 6 is formed, and at the surface of this diffusion hardened layer 6, a compound layer 7 is formed. The port portion of this die 1 is the same in cross-sectional structure as the structure shown in FIG. 6.

Next, the surface treatment method of an aluminum extruding die according to the present invention will be explained below.

The surface treatment method of an aluminum extruding die according to the present invention includes:

(1) a first nitriding treatment step for forming a diffusion hardened layer containing carbon and nitrogen in a surface layer portion of a die main body by heating and retaining a die main body made of tool steel in a nitriding gas atmosphere containing carburizing gas; and

(2) a second nitriding treatment step for forming a compound layer not substantially containing carbon on a surface of the diffusion hardened layer by heating and retaining the die main body to which the first nitriding treatment step was executed in a nitriding gas atmosphere not containing carburizing gas.

In the present invention, various kinds of tool steel can be used as base metal of a die. Examples include Cr—W-V series alloy steel represented by, e.g., JIS (Japanese Industrial Standards) SKD4 or 5, Cr—Mo—V series alloy steel represented by JIS SKD6, 61 or 7, Cr—W—Mo—V series alloy steel represented by JIS SKD62 or 8, and Ni—Cr—Mo series alloy steel represented by JIS SKT3 or 4. It is especially preferable that the tool steel is hot work tool steel to which hardening treatment and tempering treatment were executed. With this, the base metal of the die can be increased in intensity.

At the first nitriding treatment step, the die main body made of tool steel is heated and retained in the nitriding gas atmosphere containing carburizing gas to thereby form a diffusion hardened layer containing carbon and nitrogen in the surface layer portion of the die main body.

As the nitriding gas (gas for nitriding treatment) used as the atomospheric gas, NH₃ gas, or mixed gas of NH₃ gas and the non-nitriding gas, such as, e.g., N₂, can be used. Carburizing gas (e.g., RX gas), such as, e.g., converted gas of butane or propane, is mixed in the nitriding gas.

The heating temperature at the aforementioned first nitriding treatment step is preferably set to 500 to 580° C. because of the following reasons. If the heating temperature is below 500° C., the retention time for securing sufficient thickness of the compound layer and the diffusion hardened layer supporting the compound layer becomes too long, which may deteriorate the productivity. To the contrary, if the heating temperature exceeds 580° C., the softening speed of the die base metal (i.e., die main body) becomes fast, which may results in a shortened durable life of the die.

By setting the first nitriding treatment temperature to a temperature lower than the tempering treatment temperature of the die main body by several tens ° C., it becomes possible to prevent the softening of the die and secure the necessary thickness of the diffusion hardened layer and high productivity.

The retention time (i.e., processing time) of the heating temperature at the first nitriding treatment step is preferably 1 to 5 hours. In this case, a diffusion hardened layer with a sufficient thickness can be formed assuredly while securing certainly high productivity. That is, if the retention time is less than 1 hour, it sometime becomes difficult to diffuse sufficient amount of C for controlling the brittleness of the diffusion hardened layer. If the retention time is 5 hours or less, the diffusion hardened layer with a sufficient thickness can be formed assuredly. On the other hand, if the retention time exceeds 5 hours, the productivity may deteriorate.

In the present invention, however, the heating temperature and the retention time at the first nitriding treatment step are not always required to fall within the aforementioned range.

The aforementioned retention time can be changed depending on the nitriding treatment temperature so as to optimize the nitriding treatment temperature in consideration of, e.g., characteristics of the die, and can be set so that a diffusion hardened layer with a thickness sufficient enough to bear extruding conditions can be obtained.

At the second nitriding treatment step, the die main body to which the aforementioned first nitriding treatment step was performed is heated and retained in a nitriding gas atmosphere not containing carburizing gas, to thereby form a compound layer not substantially containing carbon at the surface of the diffusion hardened layer.

As the nitriding gas used as the atmospheric gas, NH₃ gas or mixed gas of NH₃ gas and non-nitriding gas, such as, e.g., N₂, can be used.

The heating temperature at the aforementioned second nitriding treatment step is preferably set to 500 to 580° C. If the temperature is below 500° C., the retaining time for securing a compound layer with a sufficient thickness becomes too long, resulting in deteriorated productivity. To the contrary, if the temperature exceeds 580° C., the softening speed of the die base metal (die main body) is too fast, which may result in a shortened durable life of the die.

By setting the second nitriding treatment temperature to a temperature lower than the tempering treatment temperature of the die main body by several tens ° C., it becomes possible to prevent the softening of the die and secure the necessary thickness of the nitrided layer and high productivity.

The retention time (i.e., processing time) of the heating temperature at the second nitriding treatment step is preferably 1 to 5 hours. In this case, the C concentration in the compound layer can be reduced assuredly, and the diffusion of the C contained in the diffusion hardened layer toward the base metal side (i.e., die main body side) can be prevented assuredly. That is, if the retention time is less than 1 hour, the C concentration in the compound layer may not be reduced sufficiently. On the other hand, if the retention time exceeds 5 hours, the C in the diffusion hardened layer may be diffused toward the base metal side by being pushed by N invading from the surface.

In the present invention, however, the heating temperature and the retention time at the second nitriding treatment step are not always required to fall within the aforementioned range.

The aforementioned retention time can be changed depending on the nitriding treatment temperature so as to optimize the nitriding treatment temperature in consideration of, e.g., characteristics of the die, and can be set so that a compound layer with a thickness sufficient enough to bear extruding conditions can be obtained.

As discussed above, in the present invention, in order to obtain the structure in which the surface compound layer is relatively hard to decompose and hard to cause separation of the diffusion hardened layer, after executing the nitriding treatment (first nitriding treatment) in the nitriding gas atmosphere containing carburizing gas having carbon source, nitriding treatment (second nitriding treatment) is subsequently performed in the nitriding gas atmosphere not containing carburizing gas. With this, both the nitrogen and the carbon are diffused in the diffusion hardened layer to thereby prevent the separation of the diffusion hardened layer by controlling the embrittlement of the layer. In addition, by reducing the carbon concentration of the compound layer formed at the outermost surface as much as possible to control the formation of carbide or carbonitride which are a compound with bonding strength to Fe weaker than an iron nitride simple substance, a compound layer hard to decompose especially at high temperature regions is formed. Thus, an aluminum extruding die of nitrided layer structure having wear resistance and separation resistance can be obtained.

As mentioned above, the aluminum extruding die to which the surface treatment was executed by the method of the present invention has nitrided layer structure having wear resistance and separation resistance and can be preferably used as an aluminum pipe extruding die especially required a relatively high extruding temperature. The aluminum extruding die can decrease the amount of wear, and hardly cause any trouble due to separation of the diffusion hardened layer, which can improve the quality of the extruded material and can expect the improvement of the productivity.

In the aluminum extruding die to which the surface treatment was executed as mentioned above, a diffusion hardened layer containing carbon and nitrogen is formed at the surface layer portion of the die main body made of tool steel, and a compound layer substantially not including carbon is formed on the surface of the aforementioned diffusion hardened layer. The tool steel is specifically hot work tool steel to which quench hardening treatment and tempering treatment were executed. It should be noted, however, that the effects of the present invention can also be obtained even in the case of using hot work tool steel to which no quench hardening treatment and tempering treatment are executed or other tool steel.

The compound layer not substantially containing carbon C contains a Fe—N compound (iron nitride) as a main ingredient, and the C concentration is preferably less than 1 mass % (especially preferably less than 0.8 mass %). In this case, this compound layer becomes hard to thermally decompose than a compound layer containing a large amount of C, resulting in outstanding wear resistance.

The thickness of this compound layer is preferably 2 to 10 μm, more preferably 4 to 8 μm. If the thickness is less than 2 μm, the extrusion amount per one time decreases and the re-nitriding treatment cycle, which will be mentioned later, becomes short, causing deteriorated productivity. To the contrary, if the thickness exceeds 10 μm, high temperature and long time treatment will be required to obtain the compound layer, which may cause deteriorated productivity of the surface treatment and reduced re-nitridable number of the die base metal of the softened die base metal.

In the present invention, however, the thickness of the compound layer is not required to fall within the aforementioned range.

On the other hand, it is required that the diffusion hardened layer does not cause a separation with the shearing stress at the time of extruding. However, the portion remarkably decreased in concentration of diffused N and decreased in Vickers hardness from about 900→600 MHv have a high probability that the tensile stress will be magnified. Therefore, considering that the stress applied from the surface decreases toward the inside, the diffusion hardened layer is preferably located at a position as nearer to the inside as possible.

Therefore, in order to enhance the separation resistance, although it is necessary to take into consideration that the magnitude of load stress changes depending on extrusion conditions, it is preferable that the thickness of the diffusion hardened layer is at least 50 μm or more, more preferably 80 μm or more. Such an aluminum extruding die will be excellent in wear resistance as well as separation resistance. Although the upper limit of the thickness of the diffusion hardened layer is not limited, it is preferable that the upper limit is especially 200 μm or less, especially 150 μm or less.

In the present invention, however, it is not required that the thickness of the diffusion hardened layer falls within the aforementioned range.

The aforementioned aluminum extruding die can be subjected to re-nitriding treatment including the aforementioned second nitriding treatment step when the compound layer formed at the aforementioned second nitriding treatment step is decreased in thickness or disappeared.

The compound layer decreases in thickness due to abrasion and decomposition at the time of extrusion. However, when the compound layer on the surface of the bearing portion which especially becomes high temperature disappears and the diffusion hardened layer is exposed, the wearing rate increases since the affinity with aluminum increases. This causes a change in bearing surface configuration, which in turn affects the dimensional accuracy of the extruded material and the quality, such as, e.g., surface roughness. As a result, the maintenance of the surface of the die after the extrusion becomes difficult, which may preclude the re-use of the die.

Therefore, by executing re-nitriding treatment before or after the disappearance of the compound layer, more preferably before the disappearance, it becomes possible to prevent the occurrence of the aforementioned troubles and extend the life of the die. With this, when the compound layer including mainly Fe₂N and Fe₃N decreased or disappeared due to extrusion and the diffusion hardened layer is exposed so that the rapid wear can be advanced, a compound layer low in carbon concentration and hard in decomposition is freshly formed, thereby enabling the re-use of the die.

In this case, when treatment including the aforementioned first nitriding treatment step and the second nitriding treatment step is executed as the aforementioned re-nitriding treatment, the re-nitriding treatment causes a further increased thickness of the diffusion hardened layer, which in turn improves the function of the diffusion hardened layer as an inclined layer which supports the compound layer and gradually reduces the hardness to the base metal. This results in the structure which hardly causes the separation of the diffusion hardened layer.

Whether or not the compound layer is remained at the time of executing the re-nitriding treatment can be discriminated by simply checking the presence of deposit of copper after dropping ammonium chloride cupric (II) aqueous solution on the die surface polished with an emery paper or the like. Therefore, the optimal re-nitriding treatment cycle can be established using this method.

As will be apparent from the above explanation, in the present invention, the nitriding treatment (the first nitriding treatment) is performed in a nitriding gas atmosphere containing carburizing gas having carbon source before executing a nitriding treatment step to simultaneously diffuse nitrogen and carbon to thereby control the brittleness of the diffusion hardened layer, and further to form a diffusion hardened layer as an inclined layer which supports the compound layer and gradually decreases the hardness to the base metal, thereby obtaining the structure hard to cause separation of the diffused hardened layer. Furthermore, the nitriding treatment (the second nitriding treatment) is executed in the nitriding gas atmosphere not containing carbon source at a later step to form a compound layer low in C concentration at the outermost surface of the diffused hardened layer. Thus, it becomes possible to make a nitrided layer ideal for an aluminum extruding die having both outstanding wear resistance and separation resistance. Therefore, this die can be preferably used to extrude 3xxx series aluminum alloy among various aluminum alloys which especially tends to cause wear of a die.

In general, the heating temperature and the extruding rate, etc., changes depending on the type of aluminum alloy to be extruded and the shape of the die, and the balance between the required wear resistance and the separation resistance differs case by case. Especially in cases where the extruding temperature is high or the requirements of the dimension and/or the surface quality is high, it is required to optimally set the thickness, etc., of the compound layer and the diffusion hardened layer. The present invention can cope with such cases by optimizing the gas composition, the temperature, time, etc., at the time of the nitriding treatment.

The production method of the aluminum extruding die according to the present invention includes a surface treatment method of the aforementioned aluminum extruding die. Accordingly, the production method of the aluminum extruding die according to the present invention has the same effects.

### EXAMPLE

Next, concrete Examples will be explained below.

### Example 1

The material (base metal) made of hot work tool steel JIS SKD61 was subjected to hardening treatment and tempering treatment to temper into HRC49. A plurality of 10×10×30 mm samples were created from this material, and the surface was polished with an emery paper #600 to obtain an analytical sample.

The analytical sample was disposed in a heating treatment furnace. In a mixed gas atmosphere of 50% NH₃+50% RX gas as nitriding gas containing carburizing gas, a first nitriding treatment was performed under the conditions of heating temperature of 560° C. and retention time of 90 minutes. Thereafter, in an atmosphere of mixed gas of 50% NH₃+50% N₂ as nitriding gas not substantially containing carburizing gas, a second nitriding treatment was performed under the conditions of heating temperature of 560° C. and retention time of 90 minutes. In this explanation, “%” denotes volume %.

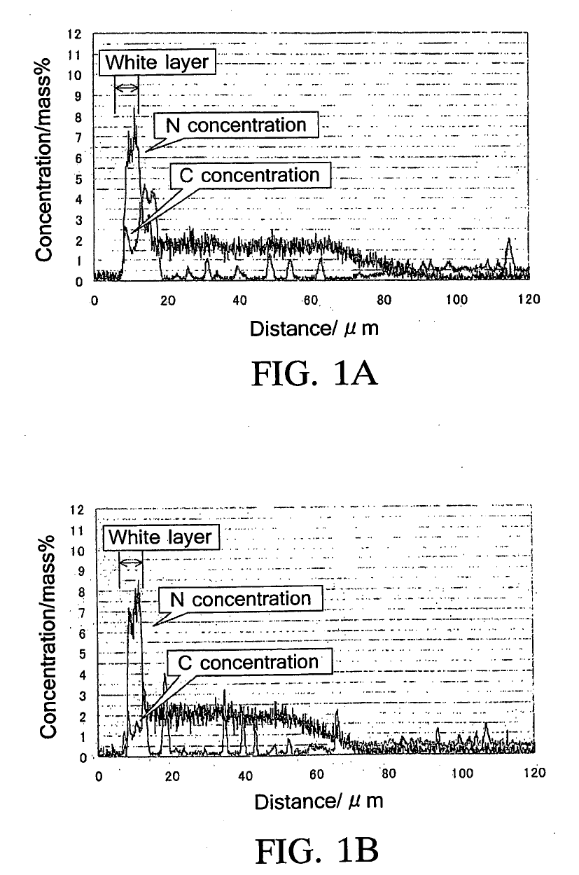

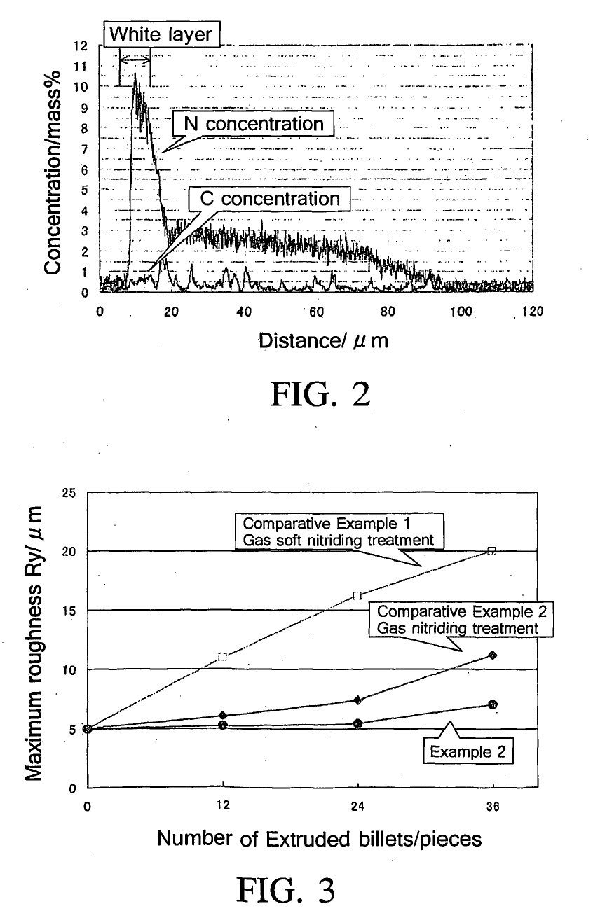

The EPMA analysis result of the cross-section of this sample is shown in FIG. 2. In this figure, a “white layer” denotes a compound layer. As shown in this figure, the C concentration corresponding to the compound layer was about 0.5 mass %, which was greatly decreased as compared with about 2 mass % which was the C concentration at the gas soft nitriding treatment and the salt bath nitriding treatment shown in FIGS. 1A and 1B. Therefore, according to this treating method, it can be expected that the wear resistance improves than conventional examples.

### Example 2

In Example 2, a pipe member was extruded from a billet of JIS 3003 aluminum alloy using an aluminum extruding die (specifically, porthole die) to which a surface treatment was executed in the same method as the aforementioned Example 1. The surface roughness of the bearing surface of this die was measured before and after the extrusion. The results are shown in FIG. 3.

### Comparative Examples 1 and 2

In Comparative Example 1, a die to which gas soft nitriding treatment was executed under the conditions of heating temperature of 560° C. and retention time of 3 hours in a mixed gas atmosphere of 50% NH₃+50% RX gas. Furthermore, in Comparative Example 2, a die to which gas nitriding treatment was executed under the conditions of heating temperature of 560° C. and retention time of 3 hours in a mixed gas atmosphere of 50% NH₃+50% N₂ gas. The base metal (die main body) of each die was the same as Example 2. Using these dies, pipe members were extruded in the same manner as in Example 1. Subsequently, the surface roughness of the bearing surface of each die was measured. The results are also shown in FIG. 3.

As shown in FIG. 3, in Comparative Example 1 in which the gas soft nitriding treatment was executed, it was observed that the surface roughness due to the quickly progressed wear was remarkably deteriorated. Similarly, in Comparative Example 2 in which gas nitriding treatment was executed, it was observed that the surface roughness due to the advanced wear was deteriorated. On the other hand, in Example 2, no remarkable wear was observed, and deterioration of the surface roughness due to the increased amount of extrusion was very few. Therefore, it was confirmed that the die according to Example 2 was excellent in wear resistance.

Furthermore, as to the dies by which extrusion was repeated 36 times, it was investigated whether there is a presence of deposit of copper after dropping ammonium chloride cupric (II) aqueous solution on the bearing surface and the port surface. The results are shown in Table 1.

TABLE 1

| | | After | After | After |
|---|---|---|---|---|
| | | extruding 12 | extruding 24 | extruding 36 |
| | | billets | billets | billets |
| Example 2 | Bearing surface | ◯ | ◯ | ◯ |
| | Port surface | ◯ | ◯ | ◯ |
| Comp. Ex. 1 | Bearing surface | X | X | X |
| (Gas soft | Port surface | ◯ | ◯ | X |
| nitriding | | | | |
| treatment) | | | | |
| Comp. Ex. 2 | Bearing surface | ◯ | ◯ | ◯ |
| (Gas | Port surface | Separated | Separated | Separated |
| nitriding | | portion X | portion X | portion X |
| treatment) | | | | |

◯: No presence of cupper deposit→remaining of a compound layer
X: Presence of cupper deposit→disappear of a compound layer

As will be apparent from Table 1, it was confirmed that at the bearing surface, there was a presence of cupper deposit and the compound layer has already disappeared only in Comparative Example 1 to which gas soft nitriding treatment was executed. This reveals that the die containing less C amount in the compound layer like Example 2 is excellent also in decomposition resistance due to heat load. Moreover, about Comparative Example 2, it was confirmed that the separation of the nitrided layer has already arisen at the port surface for introducing a billet of an aluminum alloy at the time after extruding 12 billets. From this, it was confirmed that a portion of a die with a relatively low temperature causes problems especially in brittleness.

### Example 3

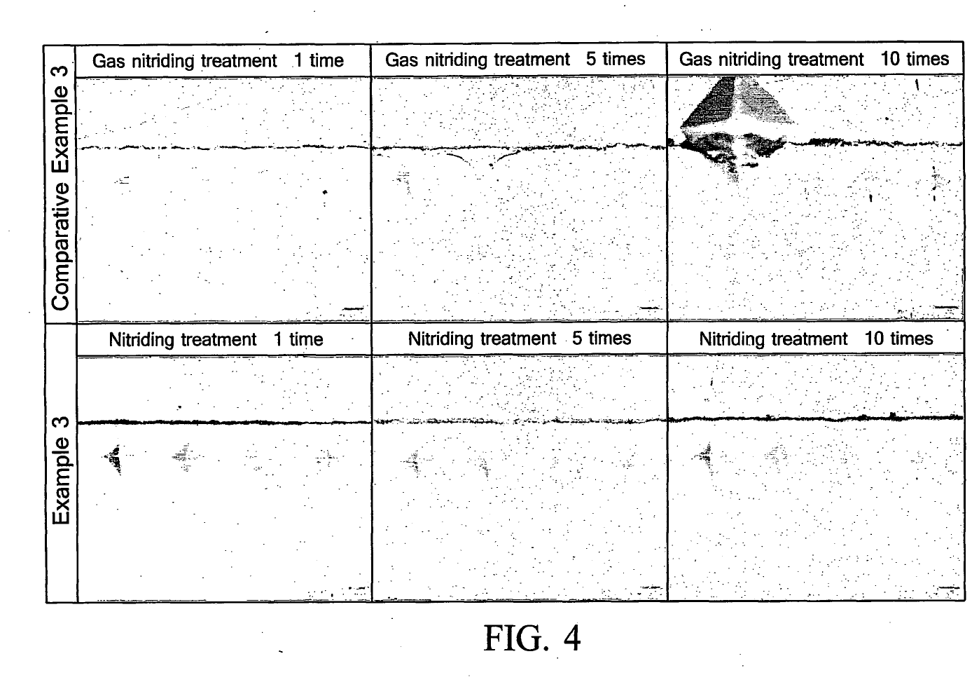

In Example 3, the same nitriding processing as in the aforementioned Example 1 was repeated to obtain test pieces to which the nitriding treatment was repeated up to 10 times. Among these test pieces, the test pieces to which the nitriding treatment was repeated 1 time, 5 times and 10 times were embedded in resin, respectively. Then, each brittleness was investigated based on whether cracks, etc., were generated by forming indentation with the load of 4.9 N at the depth of 25, 26, 27 and 28 μm from the surface using a Micro-Vickers hardness scale. The results are shown in FIG. 4.

### Comparative Example 3

In Comparative Example 3, in the same method as in the gas nitriding treatment of the aforementioned Comparative Example 2, gas nitriding treatment was repeated to obtain test pieces to which the nitriding treatment was repeated up to 10 times. In the same method as in Example 3, the brittleness was examined. The results are shown in FIG. 4.

As shown in FIG. 4, in Comparative Example 3, as the number of repetition increases, the generation of cracks of indentation became clear. For example, cracks were generated in the test piece of 5 times repetitions. Among other things, in the test pieces of 10 times repetitions, the indentation with a depth position of 25 μm collapsed (i.e., broken), resulting in a state in which the indentation cannot be normally formed. On the other hand, in Example 3, even in the test piece of 10 times repetitions, no clear crack of indentation was generated. Therefore, in Example 3, even in cases where nitriding treatment was repeated, it was confirmed that the structure low in brittleness and hard to cause separation can be obtained.

### INDUSTRIAL APPLICABILITY

The present invention can be applied to a surface treatment method of an aluminum hot extruding die, and more preferably can be applied to a surface treatment of a die for producing a pipe made of aluminum high in processing temperature.

While the present invention may be embodied in many different forms, a number of illustrative embodiments are described herein with the understanding that the present disclosure is to be considered as providing examples of the principles of the invention and such examples are not intended to limit the invention to preferred embodiments described herein and/or illustrated herein.

While illustrative embodiments of the invention have been described herein, the present invention is not limited to the various preferred embodiments described herein, but includes any and all embodiments having equivalent elements, modifications, omissions, combinations (e.g., of aspects across various embodiments), adaptations and/or alterations as would be appreciated by those in the art based on the present disclosure. The limitations in the claims are to be interpreted broadly based on the language employed in the claims and not limited to examples described in the present specification or during the prosecution of the application, which examples are to be construed as non-exclusive. For example, in the present disclosure, the term “preferably” is non-exclusive and means “preferably, but not limited to.” In this disclosure and during the prosecution of this application, means-plus-function or step-plus-function limitations will only be employed where for a specific claim limitation all of the following conditions are present in that limitation: a) “means for” or “step for” is expressly recited; b) a corresponding function is expressly recited; and c) structure, material or acts that support that structure are not recited. In this disclosure and during the prosecution of this application, the terminology “present invention” or “invention” may be used as a reference to one or more aspect within the present disclosure. The language present invention or invention should not be improperly interpreted as an identification of criticality, should not be improperly interpreted as applying across all aspects or embodiments (i.e., it should be understood that the present invention has a number of aspects and embodiments), and should not be improperly interpreted as limiting the scope of the application or claims. In this disclosure and during the prosecution of this application, the terminology “embodiment” can be used to describe any aspect, feature, process or step, any combination thereof, and/or any portion thereof, etc. In some examples, various embodiments may include overlapping features. In this disclosure and during the prosecution of this case, the following abbreviated terminology may be employed: “e.g.” which means “for example;” and “NB” which means “note well.”

1. A surface treatment method of an aluminum extruding die, comprising:
a first nitriding treatment step for forming a diffusion hardened layer containing carbon and nitrogen at a surface layer portion of a die main body by heating and retaining the die main body made of tool steel in a nitriding gas atmosphere containing carburizing gas; and
a second nitriding treatment step for forming a compound layer substantially not containing carbon on a surface of the diffusion hardened layer by heating and retaining the die main body to which the first nitriding treatment was executed in a nitriding gas atmosphere not containing carburizing gas.

2. The surface treatment method of an aluminum extruding die as recited in claim 1, wherein, at the first nitriding treatment step, heating temperature is 500 to 580° C.

3. The surface treatment method of an aluminum extruding die as recited in claim 1, wherein, at the first nitriding treatment step, retaining time is 1 to 5 hours.

4. The surface treatment method of an aluminum extruding die as recited in claim 1, wherein, at the first nitriding treatment step, the carburizing gas is converted gas of butane or propane, and the nitriding gas is NH₃ gas, or mixed gas containing NH₃ gas and non-nitriding gas.

5. The surface treatment method of an aluminum extruding die as recited in claim 4, wherein the carburizing gas is RX gas.

6. The surface treatment method of an aluminum extruding die as recited in claim 1, wherein, at the first nitriding treatment step, the diffusion hardened layer is formed to have a thickness of 50 μm or more.

7. The surface treatment method of an aluminum extruding die as recited in claim 1, wherein, at the second nitriding treatment step, heating temperature is 500 to 580° C.

8. The surface treatment method of an aluminum extruding die as recited in claim 1, wherein, at the second nitriding treatment step, retaining time is 1 to 5 hours.

9. The surface treatment method of an aluminum extruding die as recited in claim 1, wherein, at the second nitriding treatment step, the nitriding gas is NH₃ gas, or mixed gas containing NH₃ gas and non-nitriding gas.

10. The surface treatment method of an aluminum extruding die as recited in claim 1, wherein, at the second nitriding treatment step, the diffusion hardened compound layer is formed to have a thickness of 2 to 10 μm.

11. The surface treatment method of an aluminum extruding die as recited in claim 1, wherein re-nitriding treatment including the second nitriding treatment step is executed to the die when a thickness of the compound layer formed at the second nitriding treatment step is decreased or disappeared by extrusion.

12. The surface treatment method of an aluminum extruding die as recited in claim 1, wherein the die is for extruding 3xxx series aluminum alloy.

13. The surface treatment method of an aluminum extruding die as recited in claim 1, wherein the die is made of hot work tool steel to which hardening treatment and tempering treatment were executed.

14. An aluminum extruding die processed by the surface treatment method of an aluminum extruding die as recited in claim 1.

15. An aluminum extruding die in which a diffusion hardened layer containing carbon and nitrogen is formed at a surface layer portion of a die main body made of tool steel and a compound layer not substantially containing carbon is formed at a surface of the diffusion hardened layer.

16. A production method of an aluminum extruding die including the surface treatment method of an aluminum extruding die as recited in claim 1.
